(19) United States
(12) Patent Application Publication
(10) Pub. No.: US 2021/0043460 A1
(43) Pub. Date: Feb. 11, 2021

(54) MANUFACTURING METHOD OF A SEMICONDUCTOR SUBSTRATE

(71) Applicant: SEOUL VIOSYS CO., LTD., Gyeonggi-do (KR)

(72) Inventors: Hee Sub LEE, Gyeonggi-do (KR); Chae Hon KIM, Gyeonggi-do (KR)

(73) Assignee: SEOUL VIOSYS CO., LTD., Gyeonggi-do (KR)

(21) Appl. No.: 17/079,116

(22) Filed: Oct. 23, 2020

Related U.S. Application Data
(63) Continuation of application No. PCT/KR2019/005617, filed on May 10, 2019.
(60) Provisional application No. 62/670,649, filed on May 11, 2018.

(51) Int. Cl. H01L 21/304; H01L 21/321; H01L 21/02

(52) U.S. Cl. CPC H01L 21/304; H01L 21/02647; H01L 21/3212

(57) ABSTRACT

A manufacturing method of a semiconductor substrate includes forming a sacrificial layer on an upper surface of a base substrate, etching the sacrificial layer to form a plurality of concave portions and a plurality of convex portions, forming a growth suppression layer on the sacrificial layer, removing a portion of the growth suppression layer to expose an upper surface of the convex portion of the sacrificial layer, growing a semiconductor layer on the sacrificial layer, and separating the semiconductor layer from the sacrificial layer. The convex portions as a whole have a honeycomb shape, and the concave portion has a hexagonal shape, when viewed in a plan view.

### CROSS-REFERENCE OF RELATED APPLICATIONS AND PRIORITY

The present application is a continuation of PCT Application No. PCT/KR2019/005617 filed on May 10, 2019, which claims priority to U.S. Provisional Application No. 62/670,649 filed May 11, 2018, the disclosures of which are incorporated by reference in their entirety.

### TECHNICAL FIELD

The present disclosure relates to a method of manufacturing a semiconductor substrate. More particularly, the present disclosure relates to a method of manufacturing a semiconductor substrate using an epitaxial growth method.

### BACKGROUND

A nitride-based compound semiconductor has a relatively large band gap and is employed in various devices. The nitride-based compound semiconductor is employed in a light-emitting device in particular and serves as various layers.

The nitride-based compound semiconductor is manufactured by epitaxially growing a semiconductor layer on a sapphire substrate and then separating it from the sapphire substrate. However, it is difficult to form a high-quality semiconductor layer due to various types of defects in the manufacturing process, such as cracks generated in the semiconductor layer during the process of separating the semiconductor layer from the substrate.

### SUMMARY

The present disclosure provides a method of manufacturing a high-quality semiconductor substrate in which defects such as cracks are prevented.

Embodiments of the inventive concept provide a method of manufacturing a semiconductor substrate including forming a sacrificial layer on an upper surface of a base substrate, etching the sacrificial layer to form a concave portion and a convex portion, forming a growth suppression layer on the sacrificial layer, removing a portion of the growth suppression layer to expose an upper surface of the convex portion of the sacrificial layer, growing a semiconductor layer on the sacrificial layer, and separating the semiconductor layer from the sacrificial layer. The convex portion has a honeycomb shape, and the concave portion has a hexagonal shape when viewed in a plan view.

The concave portion has a closed shape defined by a plurality of sides spaced apart from a center of the concave portion by a same distance. The convex portion includes a plurality of sides, a line perpendicular to each of the sides passes through a center of the concave portion, and the concave portion has a width larger than a width of the convex portion. The concave portion is regularly arranged.

At least one of sides of the hexagonal shape is substantially parallel to a growth surface of the semiconductor layer.

At least one of sides of the hexagonal shape is substantially parallel to the (10-11) plane.

The sacrificial layer and the semiconductor layer include a same material. The sacrificial layer and the semiconductor layer include GaN.

The concave has an area three times as large as or larger than an area of the convex portion.

The convex portion has a width equal or larger than about 1 micrometer.

A distance between sides facing each other of the concave portion is six and a half times as large as or larger than the width of the convex portion.

The concave portion has a depth smaller than a thickness of the sacrificial layer. The depth of the concave portion is equal to or larger than about 0.5 micrometers. The thickness of the sacrificial layer is in a range from about 1.5 micrometers to about 2 micrometers.

A thickness of the base substrate and the sacrificial layer is equal to or smaller than about 7 micrometers.

The growing of the semiconductor layer is performed by an MOCVD using an ELOG method.

The removing of the portion of the growth suppression layer is performed by a CMP.

The sacrificial layer is dry etched.

The base substrate is a sapphire substrate.

According to the above, the method of manufacturing the high-quality semiconductor substrate in which defects such as cracks are prevented may be provided.

### BRIEF DESCRIPTION OF THE DRAWINGS

The above and other advantages of the present disclosure will become readily apparent by reference to the following detailed description when considered in conjunction with the accompanying drawings wherein:

FIGS. 1A to 1G are cross-sectional views sequentially showing a method of manufacturing a semiconductor substrate according to an exemplary embodiment of the present disclosure where;

FIG. 1A illustrates a step of forming a sacrificial layer on a base substrate;

FIG. 1B illustrates a step of etching the sacrificial layer;

FIG. 1C illustrates a step of forming a growth suppression layer;

FIG. 1D illustrates a step of removing a portion of the growth suppression layer;

FIG. 1E illustrates a step of growing a semiconductor layer on an exposed sacrificial layer;

FIG. 1F illustrates a step of growing the semiconductor layer in an upward direction and a lateral direction; and

FIG. 1G illustrates a step of separating the semiconductor layer from the sacrificial layer;

FIG. 2 is a plan view showing a shape of a concave portion and a convex portion of a sacrificial layer;

FIG. 3A is a SEM image showing a growth process of a semiconductor layer;

FIG. 3B is a SEM image showing a semiconductor layer whose merging is completed after the growth of the semiconductor layer; and

FIG. 4 is a cross-sectional view showing a lateral type light emitting device as a light emitting device according to an exemplary embodiment of the present disclosure.

### DETAILED DESCRIPTION

The present disclosure may be variously modified and realized in many different forms, and thus specific embodiments will be exemplified in the drawings and described in detail hereinbelow. However, the present disclosure should not be limited to the specific disclosed forms, and be construed to include all modifications, equivalents, or replacements included in the spirit and scope of the present disclosure.

Hereinafter, exemplary embodiments of the present disclosure will be explained in detail with reference to the accompanying drawings. Embodiments of the present disclosure relate to a manufacturing method of a nitride-based compound semiconductor. The nitride-based compound semiconductor (hereinafter, referred to as a “semiconductor”) is a compound semiconductor represented by the following general formula of AlₓGa_{y}N (0≤x≤1, 0≤x+y<1, 0≤x+y≤1) and is defined as including a compound semiconductor doped with a p-type or n-type impurity.

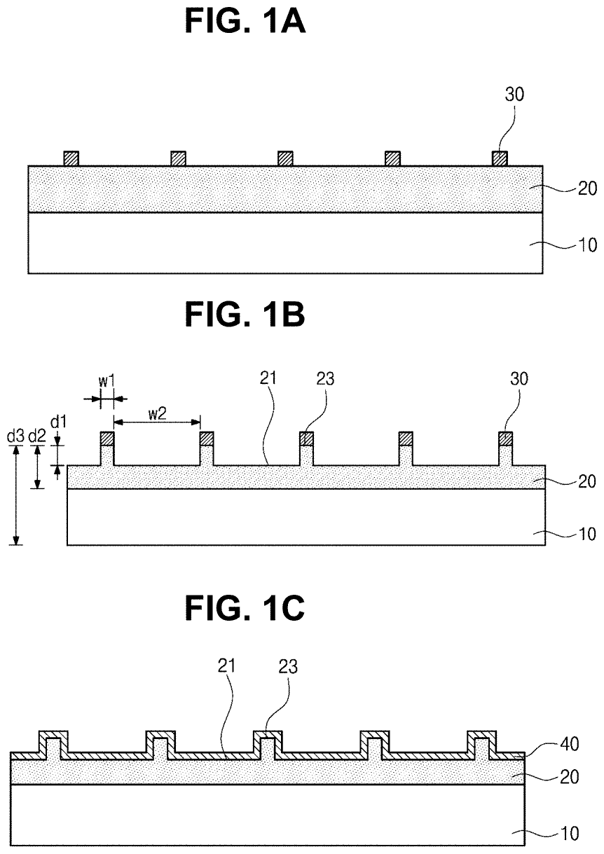

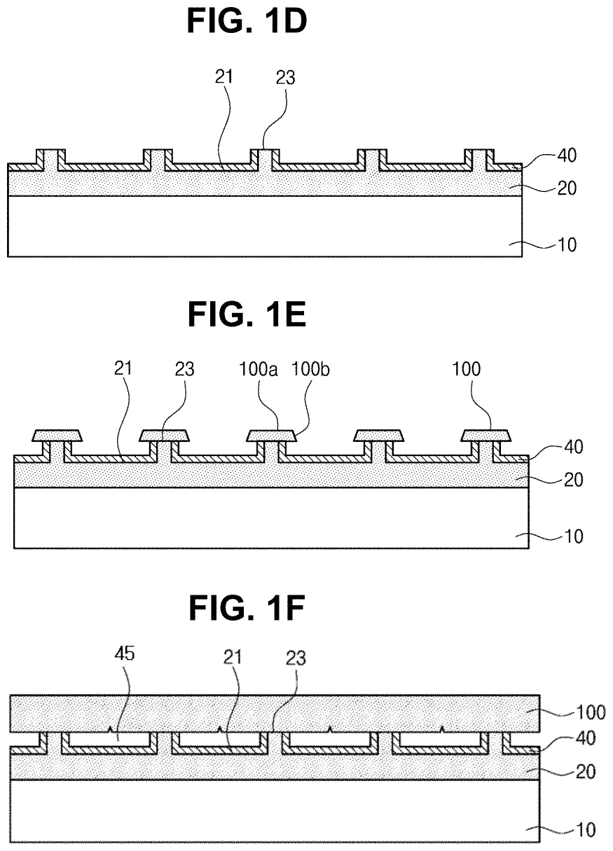

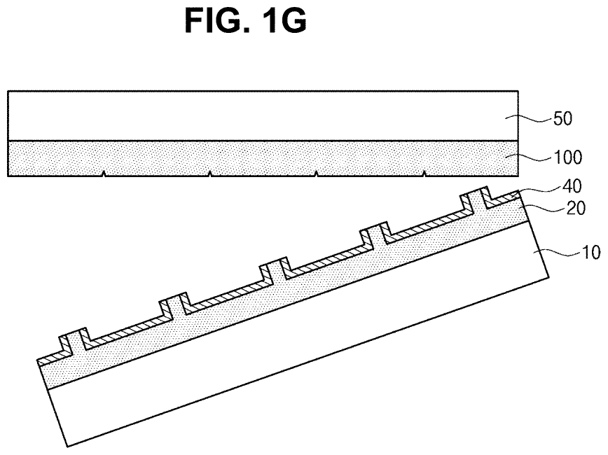

FIGS. 1A to 1G are cross-sectional views sequentially showing a method of manufacturing a semiconductor substrate according to an exemplary embodiment of the present disclosure.

Referring to FIG. 1A, a sacrificial layer 20 is formed on a base substrate 10. The base substrate 10 may be a growth substrate for growing the sacrificial layer 20, and a sapphire substrate may be used in this embodiment. However, a material for the substrate should not be limited thereto or thereby, and the substrate may include various materials, e.g., SiC, Si, GaAs, GaN, ZnO, GaP, InP, Ge, Ga₂O₃, etc.

The sacrificial layer 20 may be a nitride-based compound semiconductor layer. For example, the sacrificial layer 20 may be a compound semiconductor represented by the general formula of AlₓGa_{y}N (0≤x≤1, 0<y≤1) and may be GaN in the exemplary embodiment of the present disclosure.

A pattern mask 30 is formed above the base substrate 10 on which the sacrificial layer 20 is formed to pattern the sacrificial layer 20 later. The pattern mask 30 is used to pattern the sacrificial layer 20 and is formed by taking into account a shape to be patterned. In the exemplary embodiment of the present disclosure, the pattern mask 30 has a honeycomb shape when viewed in a plan view. Since the pattern mask 30 is used as a mask to etch the sacrificial layer 20, the shape of the pattern mask 30 in the plan view substantially matches with a shape of the sacrificial layer 20, which is etched, in the plan view. Accordingly, the sacrificial layer 20 will be mainly described with reference to accompanying drawings.

Referring to FIG. 1B, the sacrificial layer 20 formed on the base substrate 10 is etched using the pattern mask 30 as the mask.

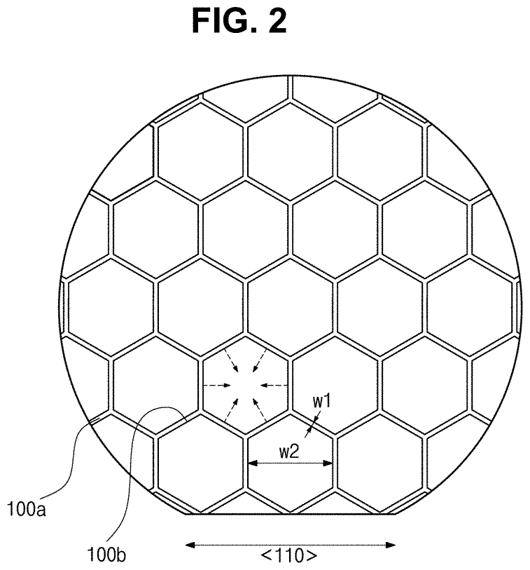

FIG. 1B shows the substrate 10 and the sacrificial layer 20 when viewed in a cross-section, and the sacrificial layer 20 is etched so that an upper surface thereof has a concave portion 21 and a convex portion 23. Shapes of the concave portion 21 and the convex portion 23 of the sacrificial layer 20 are shown in FIG. 2.

Referring to FIGS. 1B and 2, since the sacrificial layer 20 is etched using the pattern mask 30 of FIG. 1A, the convex portion 23 has substantially the same shape as the shape of the pattern mask 30 when viewed in a plan view.

In the exemplary embodiment of the present disclosure, the convex portion 23 has the honeycomb shape when viewed in a plan view, and the concave portion 21 is recessed in a hexagonal shape when viewed in a plan view. In this case, at least one side among sides of the hexagonal shape may be set to be substantially parallel to a growth surface of the semiconductor layer 100. The concave portion 21 and the convex portion 23 of the sacrificial layer 20 will be described later.

The sacrificial layer 20 may be patterned by various methods, and in the exemplary embodiment of the present disclosure, may be patterned by a dry etching process. The pattern mask 30 is removed after the patterning of the sacrificial layer 20 is completed, as shown in FIG. 1C.

Referring to FIG. 1C, a growth suppression layer 40 is formed on the sacrificial layer 20 after the pattern mask 30 is removed. The growth suppression layer 40 may include various materials, and in the exemplary embodiment of the present disclosure, may include an inorganic material, such as SiO₂ and SiNₓ. The growth suppression layer 40 is a layer which prevents an epitaxial growth of a semiconductor layer, which is to be described later, on the upper surface thereof.

Referring to FIG. 1D, a portion of the growth suppression layer 40 is removed to expose a portion of the sacrificial layer 20. The exposed portion of the sacrificial layer 20 corresponds to an upper surface of the convex portion 23.

In the exemplary embodiment of the present disclosure, the growth suppression layer 40 may be removed by various ways. For example, the growth suppression layer 40 may be removed by a chemical mechanical polishing (CMP) in the exemplary embodiment of the present disclosure. In this case, a portion of the upper portion of the convex portion 23 may be removed together with the growth suppression layer 40. However, according to another embodiment of the present disclosure, the portion of the growth suppression layer 40 may be removed by another process rather than the Chemical Mechanical Polishing (CMP) process. For example, the portion of the growth suppression layer 40 may be removed by an etch back process. The etch back process may be performed by coating a photoresist or a spin-on-glass (SOG) and by etching the growth suppression layer 40 using the photoresist or the spin-on-glass (SOG). In this case, the etching may be dry etching.

As the portion of the growth suppression layer 40 is removed, only the upper surface of the convex portion 23 is exposed to the outside, and side surfaces of the concave portion 21 and the convex portion 23 are covered by the growth suppression layer 40.

Referring to FIG. 1E, the exposed upper surface of the sacrificial layer 20 is nucleated, and the semiconductor layer 100 is grown on the exposed sacrificial layer 20.

The semiconductor layer 100 may be formed by using the same or similar nitride-based semiconductor compound material as the sacrificial layer 20. In the exemplary embodiment of the present disclosure, the sacrificial layer 20 and the semiconductor layer 100 may be formed of the same material. For example, the sacrificial layer 20 is formed of GaN, and the semiconductor layer 100 may also be formed of GaN. However, although the sacrificial layer 20 and the semiconductor layer 100 are formed of the same material, there may be a difference in impurity or a difference in composition ratio.

FIG. 1F illustrates that the semiconductor layer 100 is grown in an upward direction as well as a lateral direction from the exposed surface of the sacrificial layer 20. In the exemplary embodiment of the present disclosure, a film formation of the semiconductor layer 100 proceeds under a film formation condition that causes the growth, particularly in the lateral direction (horizontal direction in FIGS. 1E to 1F), to occur rapidly. To this end, the semiconductor layer 100 may be film-formed by a metal-organic chemical vapor deposition (MOCVD) method using an epitaxial lateral over-growth (ELOG).

The semiconductor layer 100 is continuously grown in the lateral direction so that edges of the finally grown semiconductor layer 100 are merged or converged, and thus the semiconductor layer 100 has a plate shape covering all portions where the concave portion 21 is formed, as shown in FIG. 1F.

The film formation may be mainly performed along the lateral direction until crystals of the semiconductor layer 100 are completely merged along the horizontal direction by the ELOG method, as shown in FIG. 1F.

In the exemplary embodiment, since the sacrificial layer 20 includes the concave portion 21 and the growth suppression layer 40 is formed on the concave portion 21, the growth of the semiconductor layer 100 is suppressed on the concave portion 21. Therefore, the semiconductor layer 100 and the concave portion 21 may be spaced apart from each other.

In the exemplary embodiment of the present disclosure, since the semiconductor layer 100 is grown in the lateral direction and is not grown on the concave portion 21, a void 45, i.e., an area where the semiconductor layer 100 is not formed or grown, is formed. Accordingly, the void 45 is defined in an area corresponding to the concave portion 21 of the sacrificial layer 20 under the semiconductor layer 100. A lower surface of the semiconductor layer 100 and the sacrificial layer 20, more specifically, the lower surface of the semiconductor layer 100 and the upper surface of the growth suppression layer 40 may be spaced apart from each other in the area in which the void 45 is defined, and only the upper surface of the convex portion 23 and the lower surface of the semiconductor layer 100 make contact with each other.

The semiconductor layer 100 may be further grown using an Hydride Vapor Phase Epitaxy (HVPE) after the entire semiconductor layer 100 is merged or converged through the lateral growth. A film formation rate of the semiconductor layer 100, when film-forming the semiconductor layer 100 using the MOCVD, is slower than a film formation rate of the semiconductor layer 100 using the HVPE. In other words, using HVPE is helpful to quickly grow the semiconductor layer 100 with a sufficient thickness. However, using the MOCVD is helpful to maintain or reduce a resistance against stress, which occurs during the process of separating the base substrate using a temperature difference.

Referring to FIG. 1G, the semiconductor layer 100 and the sacrificial layer 20 are separated from each other. Because the semiconductor layer 100 and the sacrificial layer 20 merely make contact with each other only in an area corresponding to the upper surface of the convex portion 23 and are not in contact with each other in an area that is much wider than the contact area, the semiconductor layer 100 and the sacrificial layer 20 may be easily separated from each other by varying the process conditions. For example, after the merging the semiconductor layer 100 in the lateral direction, in the process of film-forming of the semiconductor layer 100 in the upward direction, the semiconductor layer 100 may be film-formed by the using HVPE (Hydride Vapor Phase Epitaxy). Then the semiconductor layer 100 and the sacrificial layer 20 may be separated from each other just by lowering a process temperature during the HVPE process. In the exemplary embodiment of the present disclosure, when separating the semiconductor layer 100 from the sacrificial layer 20, a supporter substrate 50 may be used to support the semiconductor layer 100, as shown in FIG. 1G.

In the exemplary embodiment of the present disclosure, the lower surface of the manufactured semiconductor layer 100 may be additionally polished. As the lower surface of the manufactured semiconductor layer 100 becomes flat by the polishing process, an additional film formation of the semiconductor layer 100 may be easily performed on the lower surface of the semiconductor layer 100. In particular, in the case where the side surface of the semiconductor layer 100 is grown in the process of film-forming the semiconductor layer 100, a V-shaped groove may be formed in the lower surface of the merging position where the semiconductor layer 100 is merged, as shown in FIG. 1G. Accordingly, the semiconductor layer having the flat upper surface may be formed by removing the groove using the polishing process. Thus, the semiconductor substrate including the semiconductor layer 100 having a plate shape is finally manufactured.

The semiconductor substrate according to the exemplary embodiment of the present disclosure has a relatively uniform epitaxy and a relatively low crack generation rate, and the semiconductor substrate may include the sacrificial layer having the predetermined shape described above to implement the relatively uniform epitaxy and relatively low crack generation rate. Hereinafter, this will be described in detail.

FIG. 2 is a plan view showing a shape of the concave and convex portions of the sacrificial layer in the manufacturing method of the semiconductor layer 100. Hereinafter, the shape of the sacrificial layer 20 and an epitaxial growth process will be described with reference to FIGS. 1A to 1E, particularly, FIG. 1B.

Referring to FIGS. 1B and 2, the sacrificial layer 20 is patterned to have the concave and convex portions. Hereinafter, the concave and convex portions will be described as the concave portion 21 and the convex portion 23. The concave portion 21 means portions recessed downward from the upper surface the sacrificial layer 20 before being patterned, and the convex portion 23 means portions protruding upward from a lower surface of the recessed concave portion 21. In this case, although sides forming a shape of the concave portion 21 and sides forming a shape of the convex portion 23 are the same sides, the sides are separately explained in connection with the concave portion 21, or the convex portion 23 for the convenience of explanation.

In the exemplary embodiment of the present disclosure, the convex portions 23 as a whole has the honeycomb shape when viewed in a plan view, and the concave portion 21 is provided at a portion corresponding to a hexagon of the honeycomb shape, as shown in FIG. 2. The concave portion 21 is provided in a plural number and may be regularly arranged such that a width of the convex portion 23 is maintained at a constant level as the sides of the concave portions 21 correspond to each other.

The concave portion 21 may have a regular hexagonal shape as a whole although there may be some minute differences. Therefore, the sides of the hexagonal shape are separated from a center of the concave portion 21 by substantially the same distance, and a line perpendicular to each side of the hexagonal shaped concave portion 21 passes through the center of the concave portion 21, as shown with dotted arrows in FIG. 2. However, it is not required for the concave portion 21 to have a perfectly regular hexagonal shape.

The convex portion 23 has a protrusion shape defined by upper and side surfaces. The upper surface of the convex portion 23 has a predetermined width w1 when viewed in a plan view such that the epitaxial growth of the semiconductor layer 100, particularly, the ELOG may easily occur. In the present exemplary embodiment of the present disclosure, the width w1 of the upper surface of the convex portion 23 may be equal to or greater than about 1 micrometer.

Referring to FIGS. 1E and 2, the semiconductor layer 100 is grown by the ELOG grows in the upper direction and the lateral direction using the upper surface of the convex portion 23 as a nucleus. A surface in the upper direction is referred to as an upper surface 100a and a surface in the lateral direction is referred to as a side surface 100b during the growth of the semiconductor layer 100. The growth of the side surface 100b is more dominant than the growth of the upper surface 100a due to ELOG conditions when the semiconductor layer 100 is epitaxially grown by the ELOG, and a growth ratio of an m-axis to a c-axis becomes about 2:1.

In the exemplary embodiment of the present disclosure, the side surface 100b of the semiconductor layer 100 may be perpendicular to the upper surface 100a of the semiconductor layer 100 during the growth of the semiconductor layer 100; however, the present disclosure should not be limited thereto or thereby. In other embodiments, the side surface 100b of the semiconductor layer 100 may be a facet surface inclined with respect to the upper surface 100a of the semiconductor layer 100. In the exemplary embodiment of the present disclosure, the upper surface 100a of the semiconductor layer 100 corresponds to (0001) plane, and the side surface 100b of the semiconductor layer 100 corresponds to (10-11) plane.

When viewed in a plan view, the shape of the convex portion 23 (or the shape of the concave portion 21) is an important factor for controlling the growth direction from the side surface 100b of the semiconductor layer 100. The lateral growth direction of the semiconductor layer 100 may be different depending on an extending direction of each side of an edge. In the exemplary embodiment of the present disclosure, the lateral growth direction of the semiconductor layer 100 is arranged to be oriented toward the center of the hexagonal shape, and the side surface of the convex portion 23 corresponds to the (10-11) plane so that the ELOG mainly occurs in the MOCVD. That is, when viewed in a plan view, the side surface of the convex portion 23 corresponding to each side of the hexagonal shape is formed substantially parallel to the (10-11) plane of the semiconductor layer 100.

In the exemplary embodiment, the side surface of the convex portion 23 may be perpendicular to the lower surface of the concave portion 21; however, it should not be limited thereto or thereby. That is, the side surface of the convex portion 23 may be formed to be inclined as to the lower surface of the concave portion 21.

Referring to FIGS. 1B to 1G again, the concave portion 21 is formed by removing the sacrificial layer 20 from the upper surface of the sacrificial layer 20 to a predetermined depth and is formed to provide the void 45 between the semiconductor layer 100 and the sacrificial layer 20. The semiconductor layer 100 may be easily separated from the sacrificial layer 20 due to the void 45 after the semiconductor layer 100 is formed.

To this end, the concave portion 21 is formed with a depth sufficient to be spaced apart from the semiconductor layer 100 that is film-formed, after the growth suppression layer 40 is formed. However, the depth d1 of the concave portion 21 is smaller than a thickness d2 of the sacrificial layer 20, as shown in FIG. 1B. For example, in the exemplary embodiment of the present disclosure, the thickness d2 of the sacrificial layer 20 may be within a range from about 1.5 micrometers to about 2 micrometers, and the depth d1 of the concave portion 21 may be smaller than the thickness d2 of the sacrificial layer 20. If the depth d1 of the concave portion 21 is equal to or greater than the thickness d2 of the sacrificial layer 20, the upper surface of the base substrate 10 may be exposed to the outside, and as a result, the cracks are likely to occur due to the stress in the epitaxial growth and merging process of the semiconductor layer 100 in the lateral direction. Accordingly, when the thickness d2 of the sacrificial layer 20 is in a range from about 1.5 micrometers to about 2 micrometers, the depth d1 of the concave portion 21 may be within a range from about 0.5 micrometers to about 1 micrometer by taking into account a process margin.

In addition, the concave portion 21 has a width and an area that are sufficient to facilitate the separation of the semiconductor layer 100 from the sacrificial layer 20 after the formation of the semiconductor layer 100 is completed. Particularly, the area of the upper surface of the convex portion 23 where the epitaxial growth directly occurs and the area of the concave portion 21 that is an empty space are set to appropriate values so that the epitaxial growth of the semiconductor layer 100 easily occurs and the semiconductor layer 100 is easily separated later. In the exemplary embodiment of the present disclosure, the area of the concave portion 21 may be three times as larger as or larger than the area of the convex portion 23 when viewed in a plan view. In addition, a distance w2 between sides facing each other of the concave portion 21 may be six and a half times as large as or larger than the width w1 of the convex portion 23. If the area or the distance w2 between the sides facing each other of the concave portion 21 are smaller than the area or the distance w1 between the sides facing each other of the convex portion 23, it may be difficult to separate the semiconductor layer 100 from the sacrificial layer 20.

It is more advantageous to increase the area of the concave portion 21 and the distance between the sides facing each other of the concave portion 21 to facilitate the separation However, when the area and distance of the concave portion 21 become greater than the predetermined values, the stress due to a difference in thermal expansion coefficient between the base substrate 10 and the sacrificial layer 20 may occur during the process. This stress may lead to the cracks in the sacrificial layer 20 and the semiconductor layer 100 grown on the sacrificial layer 20. When the semiconductor layer 100 is epitaxially grown, in particular, in a case where the semiconductor layer 100 is merged by the MOCVD and an additional growth is performed with the HVPE at a later stage, the semiconductor layer 100 is exposed to a room temperature in a moving section. In this case, the stress due to the difference in thermal expansion coefficient between the base substrate 10 and the sacrificial layer 20 may occur. In order to prevent this stress, the areas of the concave portion 21 and the convex portion 23 of the sacrificial layer 20 may be set to tolerate the stress due to the difference in the thermal expansion coefficient and prevent the cracks due to the stress. In addition, the base substrate 10 and the sacrificial layer 20 may have a thickness that can tolerate the stress due to the difference in thermal expansion coefficient between the base substrate 10 and the sacrificial layer 20. A sum d3 of the thickness of the base substrate 10 and the thickness of the sacrificial layer 20 may be set to be equal to or smaller than about 7 micrometers by way of example only.

In the above-described structure, the epitaxial growth direction of the semiconductor layer 100 on the plane surface is oriented toward the center of each hexagonal shape. (See FIG. 2). That is, a direction to which the side surface 100b of the semiconductor layer 100 is epitaxially grown is a direction perpendicular to the side of each hexagonal shape and is oriented toward the center of each hexagonal shape. Therefore, the semiconductor layer 100 grows in the upward direction and, substantially simultaneously, the (10-11) plane sequentially grows toward the center direction of the hexagonal shape, thereby finally being merged with only a c-plane remaining at the center of the hexagonal shape.

According to the exemplary embodiment of the present disclosure, since the direction in which the (10-11) plane is grown is set toward the center direction of each hexagonal shape, the semiconductor layer 100 is grown in a direction opposite to a radial direction as indicated by the dotted arrow in FIG. 2. In this case, since the convex portion 23 as a whole has the honeycomb shape and the convex portions 23 adjacent to each other are entirely connected to each other, the entire thickness may be uniform regardless of its position during the epitaxial growth due to a migration of each material molecule during the growth. As described above, since the semiconductor layer 100 is epitaxially grown in a state of being connected to each other as a whole, a discontinuous surface that may occur during the growth is minimized. Thus, the semiconductor layer 100 according to the exemplary embodiment of the present disclosure may be structurally stable since a resistance generated by the discontinuous surface is significantly reduced.

If the convex portions 23 are formed in a state of being separated from each other or in a state of being distant from each other while not being separated from each other, the thickness of the semiconductor layer 100 grown from the convex portions 23 may vary lengthwise. In addition, the merging of the semiconductor layer 100 may be difficult, even though the growth continues. Even though the semiconductor layer 100 is converged as a result of the growth, a difference in thickness occurs. For example, in a case where the convex portions 23 are formed into an island shape to be spaced apart from each other or the convex portions 23 are formed in a stripe shape to be spaced apart from each other in most areas even though the edges of the convex portions 23 are connected to each other, it is difficult to obtain the semiconductor layer 100 having uniform thickness and crystal structure since the convex portions 23 are separately grown with the spaced portions therebetween.

There are various methods for epitaxially growing a semiconductor layer and each method offers different advantages. For instance, according to the teachings of the present disclosure, the process of merging the semiconductor layer 100 grown by growing the (10-11) plane in all directions using the ELOG may use the MOCVD method.

If the HVPE method may be used to epitaxially grow the semiconductor layer instead of the MOCVD method, the growth rate of the semiconductor layer in the HVPE is so fast, and thus it is difficult to meet the ELOG conditions. Accordingly, the growth in the upward direction is achieved rather than the lateral direction, and the semiconductor layer having a polycrystalline structure is grown on SiO₂ or SiNₓ used as a growth suppression layer. As a result, the growth of the c-plane may be disturbed, and the formation of a void such as the void like the void 45 is insufficient when the separation occurs. In this case, a probability of occurrence of cracks in the semiconductor layer increases.

If the semiconductor layer is epitaxially grown thick using only the HVPE process, processing facilities (e.g., a cold trap) for many by-products (e.g., NH₄Cl) generated in the HVPE process are required, and the scale of the processing facilities also needs to be enlarged. Accordingly, additional equipment investment is needed and its maintenance is difficult. In addition, when the semiconductor layer is epitaxially grown thick using only the HVPE process, the cracks may be easily generated due to the difference in thermal expansion coefficient between a base substrate and the semiconductor layer.

In contrast to the semiconductor layer epitaxially grown thick, the thickness of the semiconductor layer 100 formed using the HVPE may be much reduced in the method of forming the semiconductor layer 100 according to exemplary embodiment of the present disclosure. Thus, it is possible to efficiently manufacture the semiconductor layer 100 with only a small-capacity processing equipment. In addition, the semiconductor layer 100 according to the exemplary embodiment of the present disclosure may be easily separated from the base substrate 10 without causing defects as compared with a conventional laser lift-off (LLO) process. In a case where the semiconductor layer 100 is separated from the base substrate 10 using the LLO process, a maximum growth thickness of the semiconductor layer 100 is limited since the semiconductor layer 100 is vulnerable to stress generated during the LLO process even though a stress-relieving layer is separately added. Further, a laser irradiation range is narrow in the LLO process, and the semiconductor layer 100 may be cracked again due to the stress in the process of gradually separating depending on the irradiation range of the laser. Further, when the polishing process for additional lamination is performed in a state where the maximum growth thickness of the semiconductor layer 100 is not thick enough, the thickness of the substrate becomes very thin, making it difficult to use the substrate as a growth substrate.

However, according to the manufacturing method of the semiconductor layer 100 of the present disclosure, the base substrate 10 and the semiconductor layer 100 may be easily separated without causing the cracks due to the stress.

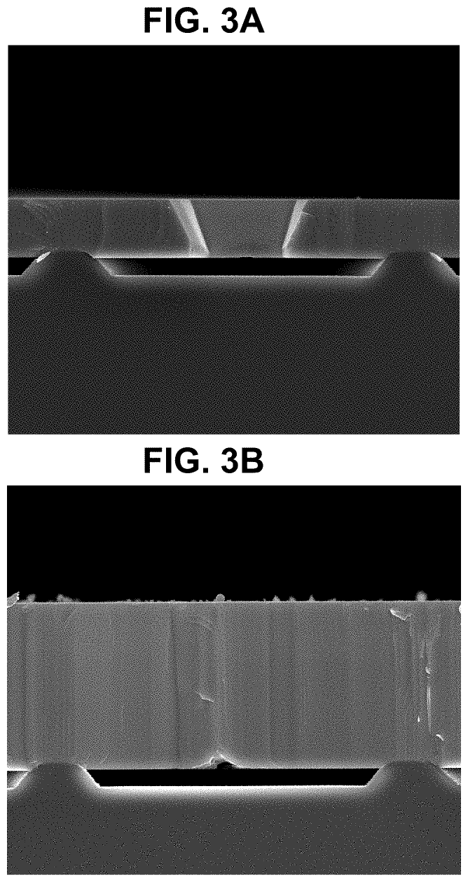

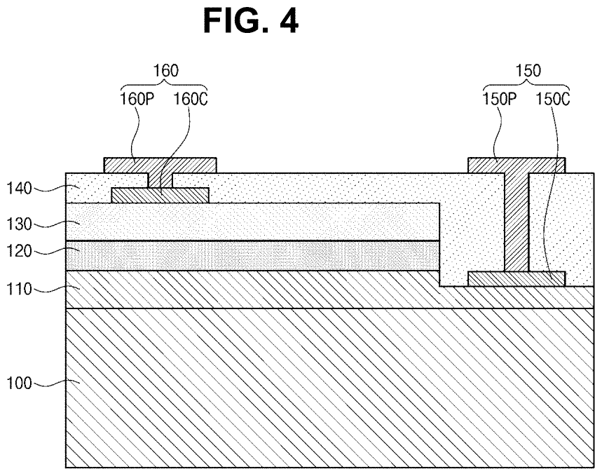

FIG. 3A is a SEM image showing a growth process of the semiconductor layer, and FIG. 3B is a SEM image showing the semiconductor layer whose merging is completed after the growth of the semiconductor layer.

In the present exemplary embodiment, considering the process margin, the sacrificial layer was formed such that a width between sides facing each other of the hexagonal shape becomes about 10.6 micrometers and a width of the upper surface of the convex portion becomes about 1.4 micrometers. In this case, a width of sides facing each other of the pattern mask was about 10 micrometers, and a width of the pattern mask above the upper surface of the convex portion was about 2 micrometers. The dimensions here are by way of example only and the present disclosure is not limited thereto. The sacrificial layer and the semiconductor layer were each formed of GaN, and the epitaxial growth of the semiconductor layer was performed under conditions that a temperature is about 1100 to about 1120 Celsius degrees, a pressure is about 150 torr, and a molar ratio of the Group V material to the Group III material (for example, the molar ratio of ammonia (NH₃) to trimethylgallium is about 2144) is about 2144. In addition, the depth of the concave portion was about 1 micrometer.

Referring to FIGS. 3A and 3B, it may be identified that a lower sacrificial layer has the concave and convex portions and the epitaxial growth of the semiconductor layer occurs on the upper surface of the concave portions of the sacrificial layer. It is clearly identified that the growing semiconductor layer has the upper surface and the side surface, and in particular, the growth in the lateral direction takes place. The side surfaces facing each other in FIG. 3A are merged with each other by the continuous growth of the semiconductor layer as shown in FIG. 3B.

The semiconductor manufactured by the above-described method may be employed in various devices, for example, the light emitting device. In the present exemplary embodiment, at least a portion of the light emitting device, for example, at least a portion of a substrate or a first semiconductor layer of a stack structure of the light emitting device may be manufactured by the above-described semiconductor manufacturing method.

FIG. 4 is a cross-sectional view showing a flip-chip type light emitting device as the light emitting device according to an exemplary embodiment of the present disclosure. However, the type of the light emitting device should not be limited thereto or thereby, and the light emitting device may be provided in another type, for example, a lateral-chip type.

For the convenience of explanation, FIG. 4 shows the light emitting device in an inverted form. However, in the exemplary embodiments of the present disclosure, terms indicating directions, such as the upper surface, the lower surface, the side surface, the upward direction, the downward direction, and the lateral direction, are set for the convenience of explanation and are relative to each other.

Referring to FIG. 4, the light emitting device according to the exemplary embodiment of the present disclosure includes a first semiconductor layer 110, an active layer 120, and a second semiconductor layer 130, which are sequentially provided on the semiconductor substrate 100.

The semiconductor substrate 100 is manufactured by the above-mentioned method and used as the growth substrate on which the first semiconductor layer 110, the active layer 120, and the second semiconductor layer 130 are grown.

The first semiconductor layer 110 is a semiconductor layer doped with a first conductive type dopant. The first conductive type dopant may be an n-type dopant. The first conductive type dopant may include Si, Ge, Se, Te, O, or C.

In the exemplary embodiment of the present disclosure, the first semiconductor layer 110 may include a nitride-based semiconductor material. For example, the first semiconductor layer 110 may include a semiconductor material having a composition formula of InₓAl_{y}Ga_{1-x-y}N(0≤x≤1, 0≤y≤1, 0≤x+y≤1). In the exemplary embodiment of the present disclosure, as the semiconductor material having the composition formula, GaN, AlN, AlGaN, InGaN, InN, InAlGaN, and AlInN may be used. The first semiconductor layer 110 may be formed by being grown to include the n-type dopant, such as Si, Ge, Sn, Se, and Te, using the semiconductor material.

The first semiconductor layer 110 may include a first sub-semiconductor layer having a relatively high impurity concentration and a second sub-semiconductor layer having a relatively low impurity concentration. The first sub-semiconductor layer may correspond to a contact layer connected to a first electrode 150 described later. The first sub-semiconductor layer and the second sub-semiconductor layer may be formed by way of sequential deposition and by controlling a deposition condition. For example, the second sub-semiconductor layer may be formed by performing a deposition process at a temperature relatively lower than that of the first sub-semiconductor layer.

In the exemplary embodiment of the present disclosure, the first semiconductor layer 110 may further have a structure in which two kinds of layers having different band gaps are alternately stacked. The structure formed by alternately stacking two kinds of layers having different band gaps may be a superlattice structure. Accordingly, the first semiconductor layer 110 may have improved current spreading and stress relief performances.

The two kinds of layers having different band gaps may be alternately formed and may respectively include thin film crystalline layers different from each other. In this case, when the two kinds of layers having different band gaps are alternately stacked, the structure may have a crystal lattice having a periodic structure longer than that of a basic unit lattice. The two layers having different band gaps include a layer having a wide band gap and a layer having a narrow band gap. In the exemplary embodiment of the present disclosure, the layer having the wide band gap may be represented by the following composition formula of AlₓGa_{y}In_{(1-x-y)}N (0≤x<1, 0<y≤1), for example, a GaN layer. The layer having the narrow band gap may be represented by the following composition formula of AlₓGa_{y}In_{(1-x-y)}N(0≤x<1, 0<y≤1), for example, may be Ga_{y}In_{(1-y)}N(0<y≤1).

In the exemplary embodiment of the present disclosure, at least one of the layer having the wide band gap and the layer having the narrow band gap may include an n-type impurity.

The active layer 120 is disposed on the first semiconductor layer 110 and corresponds to a light emitting layer.

The active layer 120 is a layer in which electrons (or holes) injected through the first semiconductor layer 110 and holes (or electrons) injected through the second semiconductor layer 130 are combined with each other to emit the light by a band gap difference of an energy band according to a material forming the active layer 120. The active layer 120 may emit at least one peak wavelength of ultraviolet light, blue light, green light, and red light.

In some embodiments, the active layer 120 may be implemented by a compound semiconductor. The active layer 120 may be implemented by, for example, at least one element of compound III-V semiconductors or compound II-VI semiconductors. The active layer 120 may have a quantum well structure and may have a multi-quantum well structure in which a quantum well layer and a barrier layer are alternately stacked. However, the structure of the active layer 120 should not be limited thereto or thereby, and the active layer 120 may have a quantum wire structure or a quantum dot structure.

In the exemplary embodiment of the present disclosure, the quantum well layer may be formed by a material represented by the following composition formula of InₓAl_{y}Ga_{1-x-y}N (0≤x≤1, 0≤y≤1, 0≤x+y≤1). The barrier layer may be formed by a material represented by the following composition formula of InₓAl_{y}Ga_{1-x-y}N (0≤x≤1, 0≤y≤1, 0≤x+y≤1) and may have a different composition ratio from the well layer. In this case, the barrier layer may have a band gap wider than a band gap of the well layer.

The well layer and the barrier layer may include at least one of pairs of AlGaAs/GaAs, InGaAs/GaAs, InGaN/GaN, GaN/AlGaN, AlGaN/AlGaN, InGaN/AlGaN, InGaN/InGaN, InGaP/GaP, AlInGaP/InGaP, and InP/GaAs. In the exemplary embodiment of the present disclosure, the well layer of the active layer 120 may be implemented by InGaN, and the barrier layer may be implemented by an AlGaN-based semiconductor. In the exemplary embodiment of the present disclosure, an indium composition of the well layer may be higher than an indium composition of the barrier layer, and the barrier layer may have no indium composition. In addition, the well layer may not include aluminum, and the barrier layer may include aluminum. However, the composition of the well layer and the barrier layer should not be limited thereto or thereby.

Meanwhile, when a thickness of the well layer is too thin, a confinement efficiency of carriers is lowered, and when the thickness of the well layer is too thick, the carriers may be over-confined. When a thickness of the barrier layer is too thin, an electron blocking efficiency is lowered, and when the thickness of the barrier layer is too thick, the electron may be blocked excessively.

Accordingly, each carrier may be effectively confined in the well layer in accordance with a wavelength of light and the quantum well structure by appropriately controlling the thickness of the barrier layer and the well layer.

In the exemplary embodiment of the present disclosure, the thickness of each well layer should not be particularly limited, and the thicknesses of the well layers may be the same as or different from each other. In the case where the thicknesses of the well layers are the same, light emission wavelengths in the well layers may be equal to each other since quantum levels are the same. In this case, a light emission spectrum with a narrow full-width-half-maximum may be obtained. In the case where the thicknesses of the well layers are different from each other, the light emission wavelengths in the well layers may be varied, and thus the light emission spectrum may be broadened.

In the exemplary embodiment of the present disclosure, at least one of the barrier layers may include a dopant, for example, may include at least one of n-type and p-type dopants. In a case where the n-type dopant is added to the barrier layer, the barrier layer may become the n-type semiconductor layer 100. When the barrier layer is the n-type semiconductor layer 100, an injection efficiency of electrons injected into the active layer 120 may increase.

In the exemplary embodiment of the present disclosure, the barrier layers may have various thicknesses. Among the barrier layers, an uppermost barrier layer may have a thickness that is equal to or greater than that of another barrier layer.

In the case where the active layer 120 has the multi-quantum well structure, a composition of the quantum well layer and the barrier layer may be set in accordance with the light emission wavelength required for the light emitting device. In the exemplary embodiment of the present disclosure, the well layers may have the same composition as each other or may have different compositions from each other. For example, the dopant may be included in the well layer in a lower side, but may not be included in the well layer in an upper side.

The second semiconductor layer 130 is disposed on the active layer 120. The second semiconductor layer 130 is a semiconductor layer doped with a second conductive type dopant having a polarity opposite to that of the first conductive type dopant. The second conductive type dopant may be a p-type dopant. The second conductive type dopant may include, for example, Mg, Zn, Ca, Sr, or Ba.

In the exemplary embodiment of the present disclosure, the second semiconductor layer 130 may include a nitride-based semiconductor material. For example, the second semiconductor layer 130 may include a semiconductor material having a composition formula of InₓAl_{y}Ga_{1-x-y}N(0≤x≤1, 0≤y≤1, 0≤x+y≤1). In the exemplary embodiment of the present disclosure, as the semiconductor material having the composition formula, GaN, AlN, AlGaN, InGaN, InN, InAlGaN, and AlInN may be used. The second semiconductor layer 130 may be formed by being grown to include the p-type dopant, such as Mg, Zn, Ca, Sr, or Ba, using the semiconductor material.

In the exemplary embodiment of the present disclosure, the first electrode 150 and a second electrode 160 are respectively disposed on the first semiconductor layer 110 and the second semiconductor layer 130 with an insulating layer 140 interposed therebetween. In detail, the second sub-semiconductor layer, the active layer 120, and the second semiconductor layer 130 may be partially removed, and as a result, a portion of the first sub-semiconductor layer is exposed. The first electrode 150 may be disposed on the exposed first sub-semiconductor layer. The second electrode 160 may be disposed on the second semiconductor layer 130.

In the exemplary embodiment of the present disclosure, the first electrode 150 may include a first contact electrode 150C that directly makes contact with the upper surface of the first semiconductor layer 110 and a first pad electrode 150P that is connected to the first contact electrode 150C via a contact hole defined through the insulating layer 140. The second electrode 160 may include a second contact electrode 160C that directly makes contact with the upper surface of the second semiconductor layer 130 and a second pad electrode 160P that is connected to the second contact electrode 160C via a contact hole defined through the insulating layer 140.

However, the structure of the semiconductor stacked structure and the first and second electrodes 150 and 160 should not be limited thereto or thereby and may be provided in various ways. For example, the semiconductor stacked structure may have one or more mesa structures, and the arrangement of the first electrode 150 and the second electrode 160 may also be provided in different locations or in different shapes depending on the mesa structure.

In the exemplary embodiment of the present disclosure, the first and second electrodes 150 and 160 may include various metal materials, for example, Al, Ti, Cr, Ni, Au, Ag, Ti, Sn, Ni, Cr, W, and Cu, or alloys thereof. The first and second electrodes 150 and 160 may have a single-layer structure or a multi-layer structure.

The above-described light emitting device may be mounted upside down on an external substrate, for example, a circuit substrate, by a conductive adhesive member. In the exemplary embodiment of the present disclosure, the conductive adhesive member may be provided with a conductive paste, such as a solder paste, a silver paste, or the like, or with a conductive resin, or may be provided with an anisotropic conductive film.

As described above, the light emitting device according to the exemplary embodiment of the present disclosure may be manufactured by forming an additional semiconductor stacked structure on the semiconductor substrate 100, which is manufactured by the above-described method, and the semiconductor stacked structure is formed on the same type of semiconductor layer or on a semiconductor layer that is a different type but has a similar crystal structure. Therefore, whether the thermal expansion coefficients of respective layers are the same as each other or different from each other, the difference between the thermal expansion coefficients is not large. Thus, when the light emitting device is driven, the stress caused by the difference between the thermal expansion coefficients is significantly reduced.

Particularly, for the light emitting device having the flip-chip form, since there is no connection structure such as gold wire which is vulnerable to heat generation, relatively more current flows, and thus, relatively more heat is generated. However, as described above, as the stress caused by the difference between the thermal expansion coefficients is significantly reduced, the defects of the light emitting device are prevented.

Although the exemplary embodiments of the present disclosure have been described, it is understood that the present disclosure should not be limited to these exemplary embodiments but various changes and modifications can be made by one ordinary skilled in the art within the spirit and scope of the present disclosure as hereinafter claimed.

Therefore, the disclosed subject matter should not be limited to any single embodiment described herein, and the scope of the present inventive concept shall be determined according to the attached claims.

What is claimed is:

1. A method of manufacturing a semiconductor substrate, comprising:
forming a sacrificial layer on an upper surface of a base substrate;
etching the sacrificial layer to form a plurality of concave portions and a plurality of convex portions;
forming a growth suppression layer on the sacrificial layer;
removing a portion of the growth suppression layer to expose an upper surface of the convex portions of the sacrificial layer;
growing a semiconductor layer on the sacrificial layer by using upper surfaces of the convex portions as a nucleus; and
separating the semiconductor layer from the sacrificial layer,
wherein the convex portions as a whole have a honeycomb shape, each concave portion is recessed to have a hexagonal shape, when viewed in a plan view, and at least one of sides of the hexagonal shaped concave portion is substantially parallel to the (10-11) plane.

2. The method of claim 1, wherein the at least one of sides of the hexagonal shaped concave portion is substantially parallel to a growth surface of the semiconductor layer.

3. The method of claim 1, wherein the sacrificial layer and the semiconductor layer comprise a same material.

4. The method of claim 1, wherein the sacrificial layer and the semiconductor layer comprise GaN.

5. The method of claim 1, wherein each concave portion has an area three times as large as or larger than an area of each convex portion.

6. The method of claim 5, wherein one of the convex portions has a width equal or larger than about 1 micrometer.

7. The method of claim 6, wherein a distance between sides facing each other of each concave portion is six and a half times as large as or larger than the width of the convex portion.

8. The method of claim 1, wherein each concave portion has a depth smaller than a thickness of the sacrificial layer.

9. The method of claim 8, wherein the depth of the concave portion is equal to or larger than about 0.5 micrometers.

10. The method of claim 8, wherein the thickness of the sacrificial layer is in a range from about 1.5 micrometers to about 2 micrometers.

11. The method of claim 10, wherein a thickness of the base substrate and the sacrificial layer is equal to or smaller than about 7 micrometers.

12. The method of claim 1, wherein growing the semiconductor layer further comprises growing the semiconductor layer with a Metal-Organic Chemical Vapor Deposition (MOCVD) method.

13. The method of claim 12, wherein growing the semiconductor layer further comprises growing the semiconductor layer with an Epitaxial Lateral Over-Growth (ELOG) method.

14. The method of claim 1, wherein removing the portion of the growth suppression layer further comprises removing the portion of the growth suppression layer with a Chemical Mechanical Polishing (CMP) method.

15. The method of claim 1, wherein etching the sacrificial layer further comprises dry etching the sacrificial layer.

16. The method of claim 1, further comprising forming the base substrate with a sapphire substrate.

17. A method of manufacturing a semiconductor substrate, comprising:
forming a sacrificial layer on an upper surface of a base substrate;
forming a plurality of concave portions and a plurality of convex portions by etching the sacrificial layer;
forming a growth suppression layer on the sacrificial layer;
removing a portion of the growth suppression layer to expose an upper surface of the convex portion of the sacrificial layer;
growing a semiconductor layer on the sacrificial layer by using upper surfaces of the convex portions as a nucleus; and
separating the semiconductor layer from the sacrificial layer,
wherein forming the concave portions further comprises forming each concave portion to have a shape defined by a plurality of sides spaced apart from a center of the concave portion by a same distance.

18. A method of manufacturing a semiconductor substrate, comprising:
forming a sacrificial layer on an upper surface of a base substrate;
forming a plurality of convex portions and a plurality of concave portions by etching the sacrificial layer;
forming a growth suppression layer on the sacrificial layer;
removing a portion of the growth suppression layer to expose an upper surface of the convex portions of the sacrificial layer;
growing a semiconductor layer on the sacrificial layer by using upper surfaces of the convex portions as a nucleus; and
separating the semiconductor layer from the sacrificial layer,
wherein each convex portion comprises a plurality of sides, a line perpendicular to each of the sides passes through a center of each concave portion, and each concave portion has a width larger than a width of the convex portion.

19. The method of claim 18, wherein the concave portions are regularly arranged.
